(19) United States
(12) Patent Application Publication
(10) Pub. No.: US 2026/0354074 A1
(43) Pub. Date: Nov. 5, 2026

(54) GAS CONTROL DEVICE

(71) Applicants: ACM RESEARCH (SHANGHAI), INC., Shanghai (CN); ACM Research Korea CO., LTD., Icheon-si (KR); CleanChip Technologies Limited, Hong Kong (CN)

(72) Inventors: Cheng Cheng, Shanghai (CN); Jun Wu, Shanghai (SH); Xuefei Deng, Shanghai (CN); Fei Xu, Shanghai (CN); Hui Wang, Shanghai (CN); Mark Lee, Icheon-si (KR)

(73) Assignees: ACM RESEARCH (SHANGHAI), INC., Shanghai (CN); ACM Research Korea CO., LTD., Icheon-si (KR); CleanChip Technologies Limited, Hong Kong (CN)

(21) Appl. No.: 19/488,418

(22) PCT Filed: May 6, 2024
(86) PCT No.: PCT/CN2024/091223

§ 371 Date: Nov. 26, 2025

(30) Foreign Application Priority Data
May 29, 2023 (CN) 202310619894.1

(51) Int. Cl. H10P 72/00; G03F 7/16

(52) U.S. Cl. CPC H10P 72/0402; G03F 7/16

(57) ABSTRACT

The present invention relates to the technical field of integrated circuit chip manufacturing, and in particular to a gas control device. The device comprises a gas intake unit, a filter plate, a diffuser plate, and a gas guide unit. The gas intake unit is formed with an opening for flowing gas to the filter plate, the filter plate is arranged corresponding to the opening, and the diffuser plate is arranged below the filter plate. The gas is vertically blown to the surface of a wafer to be processed after passing through the gas intake unit, the filter plate, and the diffuser plate in sequence. The gas guide unit comprises at least one gas guide plate, and the at least one gas guide plate is arranged at a gas guide port of the gas intake unit. The gas guide plate is added to the gas intake path, the gas guide plate guides the gas, and the partitioned gas flow is blown into the gas intake unit, so that the gas flow velocity blown to all parts on the surface of the wafer is kept uniform.

### FIELD OF THE INVENTION

The present invention relates to the technical field of integrated circuit chip manufacturing, and in particular to a gas control device.

### BACKGROUND

As shown in FIG. 1, the conventional coating and developing apparatus comprises an accommodating chamber 5 and a gas intake device, and the gas intake device is arranged above the accommodating chamber 5. Wherein, a suction platform 51, a rotating motor 52, and a photoresist nozzle (not shown) are arranged in the accommodating chamber 5. The photoresist nozzle is arranged above the center of the suction platform 51. The gas intake device comprises a filter plate 2, a diffuser plate 3, and a gas intake box 6. A wafer 7 is placed on the suction platform 51, the photoresist nozzle sprays the photoresist onto the surface of the wafer 7, the rotating motor 52 drives the wafer 7 to rotate at a high velocity, and the photoresist is spread over the entire surface of the wafer 7. During the rotation of the wafer 7, the gas intake device blows a gas having controlled temperature and humidity introduced from the outside into the accommodating chamber 5 through the gas intake box 6, the filter plate 2, and the diffuser plate 3 in sequence. The surface of the wafer 7 is coated with a uniform photoresist film under the joint action of the gas having controlled temperature and humidity.

In the above process, the introduced gas needs to be precisely controlled, in addition to the temperature and humidity, and the gas flow velocity needs to be uniform. During the coating process, the gas having controlled temperature and humidity is introduced directly above the wafer 7, and ideally, the gas needs to be blown vertically to the upper surface of the wafer 7 at a constant velocity. If the gas flow velocity is uneven, the thickness of the photoresist film on the surface of the wafer 7 will be inconsistent, and the uneven height of the photoresist film will affect subsequent chip manufacturing processes.

The current gas intake device has a vortex phenomenon, and it is difficult to ensure that the gas is blown vertically toward the upper surface of the wafer 7 at the constant velocity. The simulated gas distribution situation in the gas intake box 6 is shown in FIG. 2. Because a large vortex is formed in the upper left portion (at the dashed-line frame), the gas flow velocity blown toward the wafer 7 is uneven. The simulated flow velocity situation is shown in FIG. 3, and the gas flow velocity blown to the surface of the wafer 7 on each cross section of the gas intake device gradually increases from left to right.

### SUMMARY

In view of the above-described problem, the object of the present invention is to provide a gas control device that makes the gas flow velocity blown onto the surface of the wafer uniform.

In order to achieve the above object, the present invention provides the following technical solutions:
a gas control device, comprising a gas intake unit, a filter plate, a diffuser plate and a gas guide unit;
the gas intake unit being formed with an opening for flowing gas to the filter plate, the filter plate being arranged corresponding to the opening, and the diffuser plate being arranged below the filter plate, wherein the gas is vertically blown to the surface of a wafer to be processed after passing through the gas intake unit, the filter plate, and the diffuser plate in sequence;
the gas guide unit comprises at least one gas guide plate, and the at least one gas guide plate is arranged at a gas guide port of the gas intake unit.

The present invention also provides a gas control device, comprising a gas intake unit, a filter plate, and a diffuser plate;
the gas intake unit being formed with an opening for flowing gas to the filter plate, the filter plate being arranged corresponding to the opening, the diffuser plate being arranged below the filter plate, and the gas being vertically blown to the surface of a wafer to be processed after passing through the gas intake unit, the filter plate, and the diffuser plate in sequence;
the diffuser plate comprising a plurality of through-holes, wherein the depth of the through-holes corresponding to the first area is less than the depth of the through-holes corresponding to the second area, wherein the gas flow velocity in the first area is lower than the gas flow velocity in the second area.

Compared with the prior art, the present invention has the following beneficial effects:

The gas control device provided by the present invention comprises the gas guide plate, and the gas guide plate is arranged at the gas guide port of the gas intake unit. After passing through the filter plate and the diffuser plate in sequence through the gas intake unit, the gas having controlled temperature and humidity is vertically blown to the surface of the wafer. The gas guide plate is added to the gas intake path, the gas guide plate guides the gas, and the partitioned gas flow is blown into the gas intake unit, so that the gas flow velocity blown to all parts on the surface of the wafer is kept uniform.

The height of the through-holes is set according to the gas flow velocity at the position of the through-holes. The depth of the through-holes corresponding to the area with a low gas flow velocity is less than the depth of the through-holes corresponding to the area with a high gas flow velocity. The large depth of the through-holes hinders the discharge of the gas to a certain extent. Correspondingly, the small depth of the through-holes is more conducive to the discharge of the gas, so that the gas flow velocity blown to the surface of the wafer from all locations of the diffuser plate is kept uniform.

### BRIEF DESCRIPTION OF THE DRAWINGS

The features and performance of the present invention are further described by the following embodiments and the accompanying drawings of the embodiments.

FIG. 1 is a schematic structural view of a conventional coating and developing apparatus.

FIG. 2 is a view of the gas distribution situation in the prior art.

FIG. 3 is a view of the gas flow velocity situation in the prior art.

FIG. 4 is a schematic view of the three-dimensional structure of the gas control device provided by the present invention.

FIG. 5 is a top view of the gas control device provided by the present invention.

FIG. 6 is a first schematic structural view of the gas guide unit provided by embodiment 1 of the present invention.

FIG. 7 is a schematic structural view of the gas guide plate provided by embodiment 1 of the present invention.

FIG. 8 is a schematic view showing the connection between the single gas guide plate and other components provided by embodiment 1 of the present invention.

FIG. 9 is a side view of the single gas guide plate and other components provided by embodiment 1 of the present invention.

FIG. 10 is a view showing the gas distribution situation provided by embodiment of the present invention.

FIG. 11 is a view showing the gas flow velocity situation provided by embodiment of the present invention.

FIG. 12 is a schematic structural view of the diffuser plate provided by embodiment 1 of the present invention.

FIG. 13 is a schematic structural view of a control area provided by an embodiment of the present invention.

FIG. 14 is a cross-sectional structural view of a control area provided by an embodiment of the present invention.

FIG. 15 is a schematic view of the gas guide unit provided by another embodiment of the present invention.

FIG. 16 is a schematic view of the connection between the single gas guide plate and other components provided by another embodiment of the present invention.

FIG. 17 is a perspective structural view of a control area provided by yet another embodiment of the present invention.

FIG. 18 is a top view of the diffuser plate provided by yet another embodiment of the present invention.

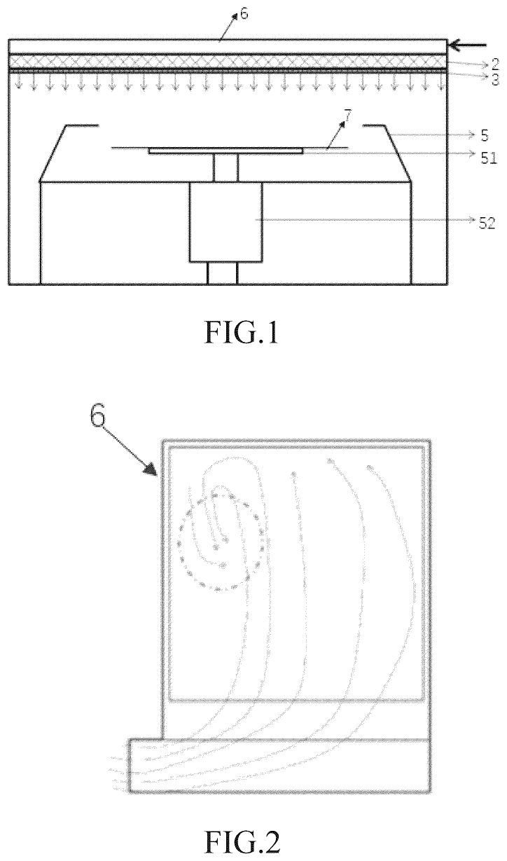

### PREFERRED EMBODIMENTS OF THE INVENTION

In order to more clearly explain the technical solutions of the embodiments of the present application, the accompanying drawings that need to be used in the description of the embodiments will be briefly described below. Obviously, the drawings in the following description are only some examples or embodiments of the present application, and those of ordinary skill in the art can apply the present application to other similar situations based on these drawings without making creative efforts. Unless obvious from the language environment or otherwise indicated, the same reference numeral in the drawing represents the same structure or operation.

As shown in this application and claims, unless the context clearly indicates an exception, the words “a,” “an,” “one,” and/or “the” do not specifically refer to the singular and may also include the plural. In general, the terms “comprising” and “including” merely suggest the inclusion of explicitly identified steps and elements, and these steps and elements do not constitute an exclusive list, and the method or apparatus may also include other steps or elements.

Unless specifically stated otherwise, the relative arrangement of components and steps, numerical expressions, and numerical values set forth in these embodiments do not limit the scope of the present application. At the same time, it should be understood that the dimensions of the various parts shown in the accompanying drawings are not drawn to actual proportions for ease of description. Techniques, methods, and devices known to those of ordinary skill in the relevant art may not be discussed in detail, but should, where appropriate, be regarded as part of the authorized specification. In all examples shown and discussed herein, any specific value should be construed as merely exemplary and not as limitative. Therefore, other examples of the exemplary embodiments may have different values. It should be noted that the same reference numeral and letter refer to the same item in the following drawings, and therefore, once an item is defined in one drawing, it is not necessary to further discuss the item in the following drawings.

In the description of the present application, it should be understood that the orientation or positional relationship indicated by the orientation words such as “front, back, up, down, left, right,” “transverse, vertical, perpendicular, horizontal” and “top, bottom” is generally based on the orientation or positional relationship shown in the accompanying drawings, and is only for the convenience and simplification of the description of the present application. Unless stated to the contrary, these location terms do not indicate and imply that the referred device or element must have a specific orientation or be constructed and operated in a specific orientation, and therefore cannot be construed as limiting the scope of protection of the present application; The positional words “inside and outside” refer to the inside and outside with respect to the contour of each component itself.

For ease of description, spatially relative terms, such as “on,” “above,” “on the upper surface,” “upper”, etc., can be used herein to describe the spatial positional relationship of one device or feature to other devices or features as shown in the drawings. It should be understood that spatially relative terms are intended to comprise different orientations in use or operation in addition to the orientation of the devices depicted in the drawings. For example, if the devices in the accompanying drawings are inverted, the devices described as “above” or “on” other devices or configurations will then be positioned as “below” or “under” other devices or configurations. Therefore, the exemplary term “above” may include both orientations “above” and “below”. The device can also be positioned in other different ways (rotated 90 degrees or in other orientations), and the spatial relative description used herein should be interpreted accordingly.

In addition, it should be noted that the use of words such as “first” and “second” to define components is only to facilitate the distinction between corresponding components, unless otherwise stated, the above words have no special meaning, and thus cannot be understood as limiting the scope of protection of the present application. Besides, although the terms used in this application are selected from well-known and commonly used terms, some terms mentioned in the specification of this application may be selected by the applicant at his or her discretion, and the detailed meanings of the terms are set forth in the relevant parts of the description herein. Besides, it is required that the present application be understood not only by the actual terms used, but also by the meaning implied by each term.

Hereinafter, the technical solutions of the present invention will be further described with reference to the accompanying drawings and specific embodiments.

### Embodiment 1

As shown in FIG. 4, the present embodiment provides a gas control device, comprising a gas intake unit 1, a filter plate 2, a diffuser plate 3, and a gas guide unit 4.

The gas intake unit 1 is formed with an opening for flowing gas to the filter plate 2, the filter plate 2 is disposed corresponding to the opening, and the diffuser plate 3 is disposed below the filter plate 2. In the present embodiment, the diffuser plate 3, the filter plate 2, and the gas intake unit 1 are stacked sequentially from bottom to top.

The gas guide unit 4 comprises at least one gas guide plate 42, and all of the gas guide plates 42 are provided at the position of a gas guide port 13 of the gas intake unit 1. After passing through the gas intake unit 1, the gas having controlled temperature and humidity sequentially passes through the filter plate 2 and the diffuser plate 3, and is then vertically blown to the surface of a wafer to be processed.

In this embodiment, the gas guide plates 42 are added to the gas intake path of the gas intake unit 1, the gas guide plates 42 guide the gas, and the partitioned gas flow is blown into the gas intake unit 1, thereby avoiding the vortex situation in the prior art, and further keeping the gas flow velocity blown to all parts on the surface of the wafer uniform.

Specifically, as shown in FIGS. 4-5, the gas intake unit 1 includes a control area 11 and a gas intake area 12. The gas intake area 12 includes a gas inlet 121. The gas intake area 12 is provided on the side of the control area 11. The gas guide unit 4 is provided in a transition area between the control area 11 and the gas intake area 12. The transition area is provided with a gas guide port 13, the gas intake area 12 and the control area 11 are connected through the gas guide port 13, and the gas guide unit 4 is provided at the position of the gas guide port 13. The flow direction of gas in the gas intake area 12 is set to be the first flow direction A-A, and the flow direction of gas in the control area 11 is set to be the second flow direction B-B.

The gas having controlled temperature and humidity enters the control area 11 through the inside of the gas intake area 12 and the gas guide unit 4 in sequence through the gas inlet 121. The filter plate 2 is arranged below the control area 11, and the diffuser plate 3 is arranged below the filter plate 2. The gas passes through the control area 11, the filter plate 2, and the diffuser plate 3 in sequence after passing through the gas intake area 12, and is then vertically blown to the surface of the wafer.

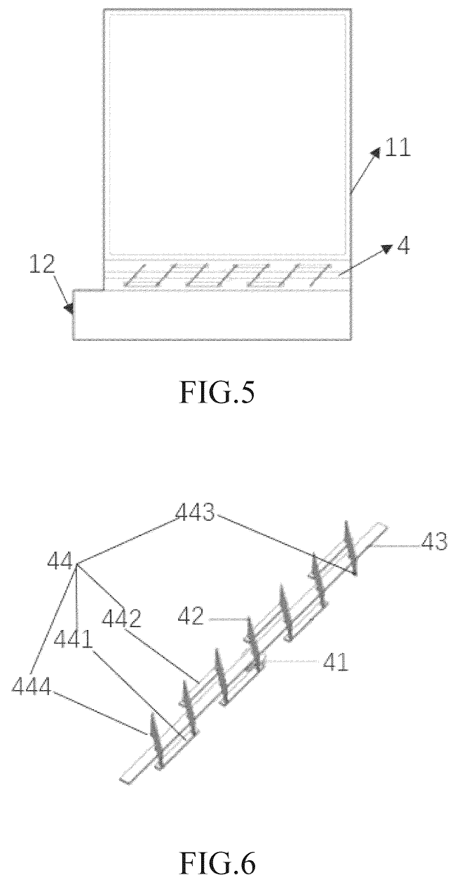

As shown in FIG. 6, the gas guide unit 4 comprises an adjustment member 41, a plurality of gas guide plates 42, a bottom plate 43, and a linkage mechanism 44, and the plurality of gas guide plates 42 are disposed at intervals. The adjustment member 41 is arranged on the bottom plate 43, the adjustment member 41 is connected to the gas guide plates 42 through the bottom plate 43, and the rotation of the adjustment member 41 is manually controlled to drive the gas guide plates 42 to swing on the bottom plate 43. The adjustment member 41 can be a knob.

The linkage mechanism 44 comprises a plurality of first connecting rods 441, a plurality of second connecting rods 442, a first connection position 443, and a second connection position 444. The first connecting rods 441 and the second connecting rods 442 are provided on both sides of the bottom plate 43, respectively. The first connecting rods 441 and the second connecting rods 442 are parallel to each other. Both ends of the gas guide plates 42 are arranged on the first connecting rods 441 and the second connecting rods 442, respectively. Both of the first connecting rods 441 and the second connecting rods 442 are provided with two gas guide plates 42. The plurality of gas guide plates 42 are arranged in parallel with each other, and the spacing between adjacent gas guide plates 42 is the same. Wherein, one end of the gas guide plate 42 at the first position is rotationally connected to the first connection position 443, and one end of the gas guide plate 42 at the last position is rotationally connected to the second connection position 444.

Alternatively, the first connection position 443 can be replaced with the first connecting rod 441, and the second connection connecting rod 444 can be replaced with the second connecting rod 442.

The adjustment member 41 is connected to one of the gas guide plates 42, and the structural design of the linkage mechanism 44 has a linkage effect. When the adjustment member 41 is manually adjusted, all the gas guide plates 42 synchronously swing at the same angle on the bottom plate 43, thereby changing the angle of the gas intake. The operator corrects the swing angle of the gas guide plates 42 in time according to the gas intake volume and the coating situation.

Alternatively, the gas guide unit 4 does not comprise the adjustment member 41. All the gas guide plates 42 are preset with the same optimum swing angle relative to the bottom plate 43, and the swing angle is fixed without adjustment. Alternatively, according to the area where the vortex is located and the affected area in the simulation result, the swing angles of different gas guide plates 42 with respect to the bottom plate 43 can be set differently.

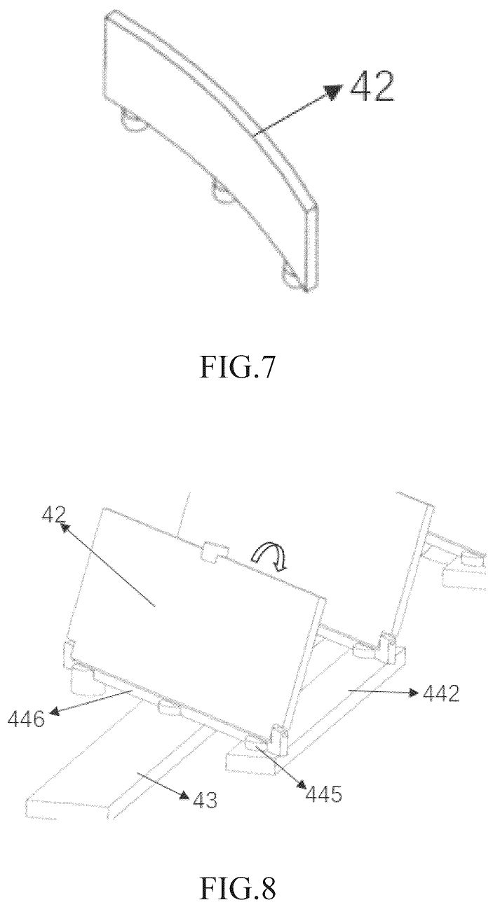

In an alternative embodiment, the gas guide plate 42 can be of a curved surface. As shown in FIG. 7, the shape of the curved surface is more conducive to the guidance of the gas flow, reduces the pressure drop of the gas flow, and further reduces the probability of the vortex formation in the gas intake unit 1.

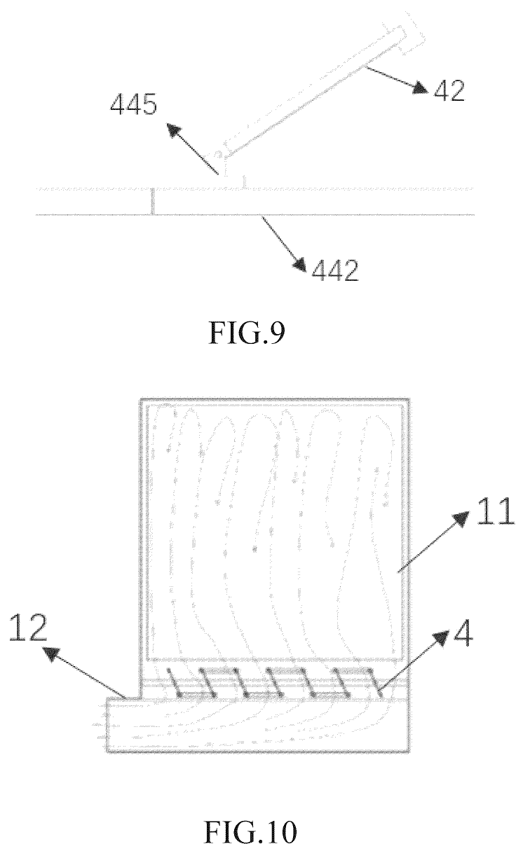

As shown in FIGS. 8-9, in order to better adjust the direction of the intaking gas flow, a first rotating shaft 446 is added to the gas guide plate 42, and rotating hinges 445 are provided on the bottom plate 43, the first connecting rod 441 (in conjunction with FIG. 6), and the second connecting rod 442. The first rotating shaft 446 is hinged to the bottom plate 43, the first connecting rod 441, and the second connecting rod 442 by a plurality of rotating hinges 445. The gas guide plate 42 rotates about the first rotating shaft 446 on the bottom plate 43 to change an inclination angle of the gas guide plate 42 with respect to the bottom plate 43. Alternatively, in an embodiment not shown, the gas guide plate 42 is directly hinged on the bottom plate 43, the first connecting rod 441, and the second connecting rod 442 by the rotating hinges 445.

Back to FIGS. 4-5, alternatively, the filter plate 2 comprises a filter body and an outer frame body surrounding the outer periphery of the filter body, the control area 11 is formed with the opening connected to the filter body, and the outer frame body is connected to the frame of the control area 11.

As shown in FIG. 12, the diffuser plate 3 comprises a plurality of through-holes 31. The gas is blown to the surface of the wafer through the through-holes 31. The uniformity of the gas flow velocity flowing out of the diffuser plate 3 determines the uniformity of the photoresist film thickness. The diffuser plate 3 comprises a proximal end area D1 and a distal end area D2, the proximal end area D1 and the distal end area D2 are sequentially arranged along the second flow direction B-B of the gas, and the proximal end area D1 is close to the gas guide port 13.

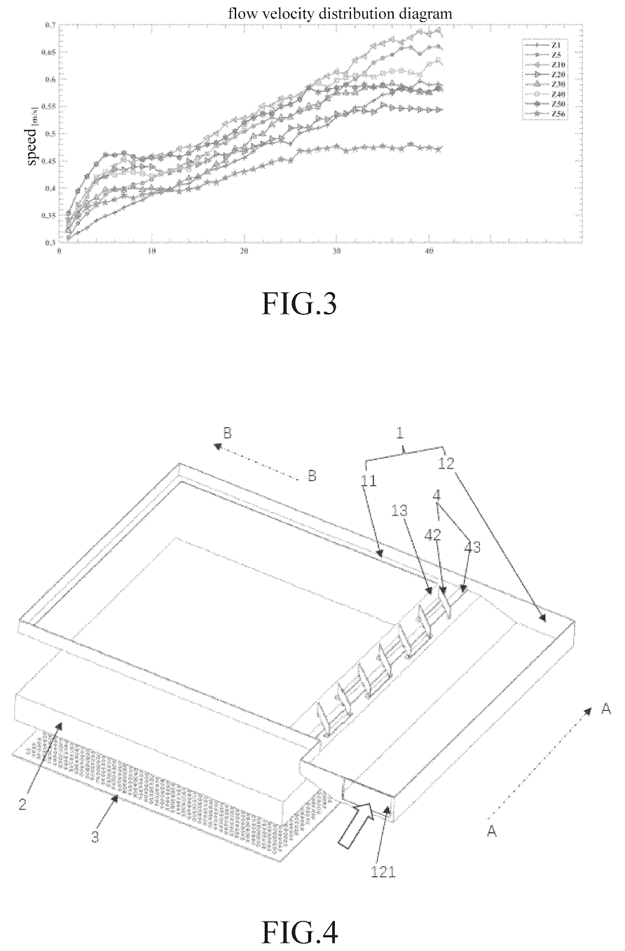

According to the flow velocity distribution diagram in the prior art in FIG. 3, the diffuser plate 3 is divided into 56 cross sections along the second flow direction B-B, and adjacent cross sections are spaced by the same distance. Z1 represents the first cross section, Z1 is close to the gas intake area 12, Z5 represents the fifth cross section, Z10 ... Z56 and so on, and 8 cross sections are selected in this embodiment.

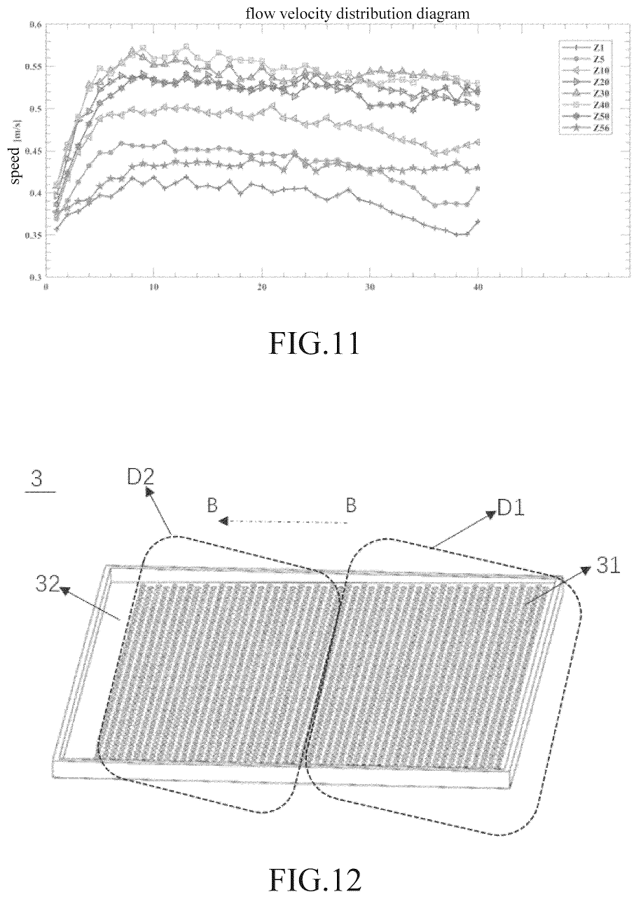

In FIG. 3, the gas flow from Z1 to Z56 is unevenly distributed, and the gas flow velocity on each cross section from the proximal end area D1 to the distal end area D2 is gradually increasing. FIG. 10 shows the gas distribution situation simulated by the gas intake unit 1 of embodiment 1, the stable output of gas can be achieved, and there is no vortex phenomenon in the control area 11. Furthermore, as shown in FIG. 11, the gas flow velocity below each through-hole 31 on each cross section is significantly improved in uniformity compared to the prior art.

With continued reference to FIG. 11, the gas flow velocity in the proximal end area D1 is smaller than the gas flow velocity in the other areas on each cross section. As shown in FIG. 12, in an alternative embodiment, the diffuser plate 3 is provided with a blocking area 32 disposed on the side of the proximal end area D1 that is away from the distal end area D2, and the blocking area 32 does not have the effect of diffusing gas. Alternatively, the size of the blocking area 32 is consistent with the size of the proximal end area D1. The blocking area 32 is provided with a blocking plate, the blocking plate does not have the through-hole or opening for the passage of gas, and the blocking plate is used to block the outflow of gas.

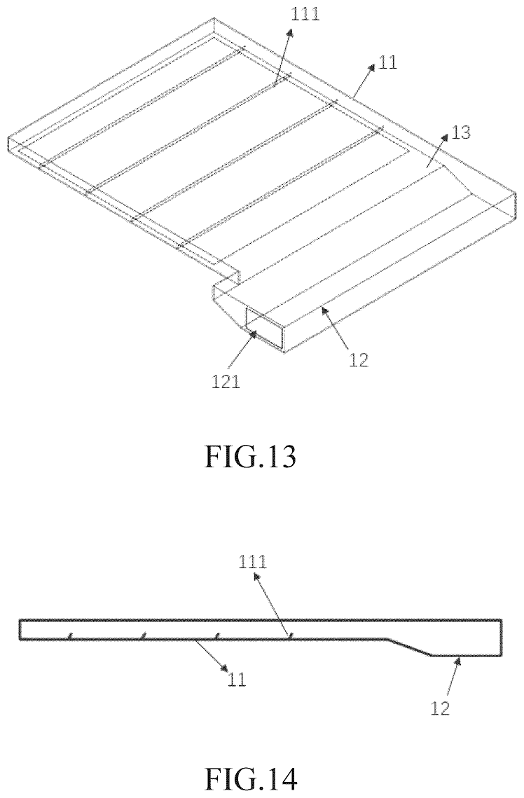

There is still a certain gap in the gas flow velocity of the through-holes on different cross sections from Z1 to Z56. The overall flow velocity of Z1, Z5, and Z10 is smaller than the overall flow velocity of Z20, Z30, Z40, and Z50, which indicates that the gas flow velocity of the through-holes 31 close to the gas intake area 12 is smaller. Alternatively, as shown in FIGS. 13-14 , a plurality of gas blocking plates 111 are arranged in the control area 11, and the gas blocking plates 111 are arranged along the direction parallel to the cross sections to block part of the gas flow at the position of the gas guide port 13, so as to increase the gas flow velocity of the through-holes 31 close to the gas guide port 13 on the diffuser plate 3. Certainly, the installation direction of the gas blocking plates 111 is not limited thereto, and the gas blocking plates 111 are inclined with respect to the cross sections. That is, there is an included angle between the installation direction of the blocking plates 111 and the second flow direction B-B.

Furthermore, a second rotating shaft (not shown) is added to the bottom of the gas blocking plates 111, the second rotating shaft is provided in the control area 11, and the gas blocking plates 111 rotate in the control area 11 through the second rotating shaft to further adjust the direction of the gas flow, thereby realizing the uniform output of the gas flow. Alternatively, adjusting the spacing between adjacent gas blocking plates 111 can further achieve the uniform output of the gas flow.

### Embodiment 2

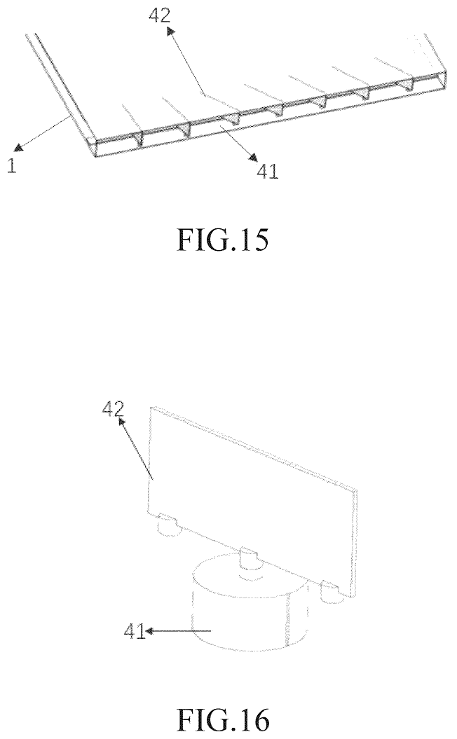

As shown in FIGS. 15-16 , embodiment 2 provides a gas control device, which is different from embodiment 1 in that a linkage mechanism 44 does not need to be designed in this embodiment.

A gas guide unit 4 comprises a plurality of gas guide plates 42 disposed at intervals and a plurality of adjustment members 41. The number and position of the adjustment members 41 are provided corresponding to the gas guide plates 42. The gas guide plates 42 are provided on the adjustment members 41. The adjustment members 41 adjust the swing angle of the corresponding gas guide plates 42 on the bottom plate 43. Alternatively, the number of gas guide plates 42 is one or two.

Before the coating process, the adjustment members 41 adjust the angle of the gas guide plates 42 so that the gas guide plates 42 are at an optimal preset angle and the gas guide plates 42 are fixed.

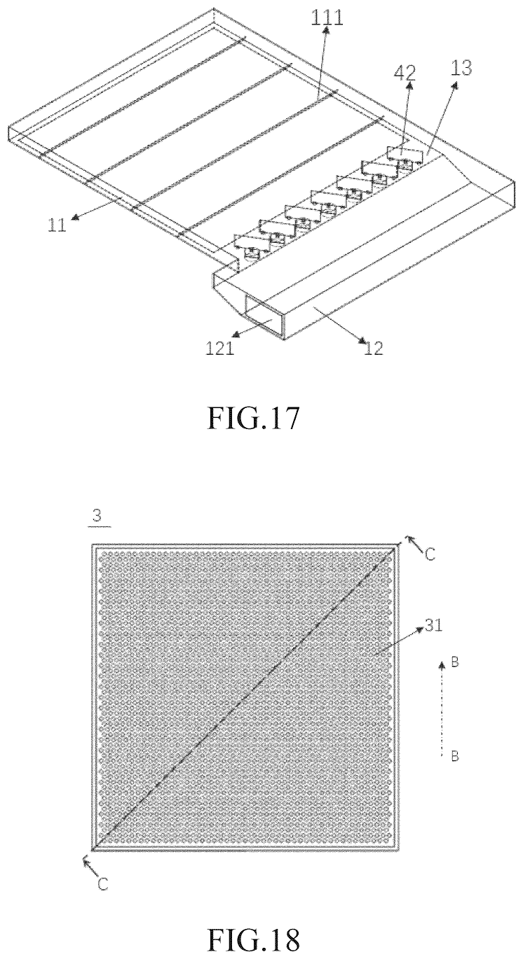

Furthermore, as shown in FIG. 17, a plurality of gas blocking plates 111 are provided in the control area 11, and the installation direction of the gas guide plates 111 is perpendicular to the second flow direction B-B of the gas to block part of the gas flow at the position of a gas guide port 13.

In this embodiment, the respective gas guide plates 42 are independent of each other, and in actual production, the swing angle of the gas guide plates 42 is adjusted more specifically according to the area where the vortex is located and the affected area.

The plurality of gas blocking plates 111 are arranged in the control area 11, and the gas guide plates 111 are arranged along the direction parallel to the cross sections to block part of the gas flow at the position of the gas guide port 13, so as to increase the gas flow velocity at the through-holes 31 close to the gas guide port 13 on a diffuser plate 3. After the gas reaches to the inside of the control area 11, the gas blocking plates 111 further adjust the flow velocity of the gas.

### Embodiment 3

With continued reference to FIGS. 3 and 18, the gas flow velocity at the lower left through-holes 31 is low, and the gas flow velocity of the upper right through-holes 31 is high. That is, it is indicated that the gas flow velocity on the side of a gas inlet 121 (in conjunction with FIG. 4) near a gas intake area 12 on each cross section is low and the gas flow velocity on the other side is high. The corresponding gas flow velocities on different flow velocity lines at the same position on the X coordinate are different, and the gas flow velocity at a position away from the gas intake area 12 is greater than the gas flow velocity at a position close to the gas intake area 12.

In the present embodiment, the height of the through-holes 31 of a diffuser plate 3 is set according to the gas flow velocity at the position of the through-holes 31. The depth of the through-holes 31 corresponding to the first area having a low gas flow velocity is smaller than the depth of the through-holes 31 corresponding to the second area having a high gas flow velocity. Herein, the high or low gas flow velocity is determined by comparation. The large depth of the through-holes 31 hinders the discharge of gas to a certain extent, and correspondingly, the small depth of the through-holes 31 is more conducive to the discharge of gas, thereby reducing the gas flow velocity at the distal end and increasing the gas flow velocity at the proximal end, so that the gas flow velocity is consistent everywhere.

Specifically, as shown in FIG. 18, the height of diagonal through-holes 31 along the diffuser plate 3 increases linearly from the proximal end to the distal end of the gas inlet 121 close to the gas intake area 12. The diffuser plate is divided into a plurality of inclined sections, the inclined sections corresponding to the diagonal line are set as reference inclined sections, the other inclined sections are set to be parallel to the reference inclined sections, and the height of the through-holes 31 on the other inclined sections increases linearly from the proximal end to the distal end.

Furthermore, the height of through-holes 31 increases toward the direction along the second flow direction B-B of the gas. Alternatively, the through-holes 31 increase linearly in height toward the direction along the second flow direction B-B of the gas.

The above has described the basic concepts, it will be obvious to those skilled in the art that the above disclosure is merely an embodiment and does not constitute a limitation of the present application. Although not explicitly stated herein, various modifications, improvements, and amendments may be made to the present application by those skilled in the art. Such modifications, improvements, and amendments are suggested in the present application, and accordingly, such modifications, improvements, and amendments remain within the spirit and scope of exemplary embodiments of the present application.

Meanwhile, specific words are used in the present application to describe embodiments of the present application. For example, “one embodiment,” “an embodiment,” and/or “some embodiments” means a certain feature, structure, or characteristic related to at least one embodiment of the present application. Therefore, it should be emphasized and noted that “an embodiment” or “one embodiment” or “an alternative embodiment” or “exemplary” referred to twice or more in different locations in this specification does not necessarily refer to the same embodiment. Besides, certain features, structures, or features in one or more embodiments of the present application can be combined as appropriate.

Similarly, it should be noted that in order to simplify the expression disclosed in the present application and thereby facilitate the understanding of one or more embodiments of the invention, in the foregoing description of the embodiments of the present application, a plurality of features may sometimes be combined into one embodiment, the drawings, or the description thereof. However, this method of disclosure does not mean that more features are required for the object of the present application than the features mentioned in the claims. In fact, the features of the embodiments are less than all of the features of the single embodiment disclosed above.

What is claimed is:

1. A gas control device, comprising a gas intake unit (1), a filter plate (2), a diffuser plate (3) and a gas guide unit (4);
the gas intake unit (1) being formed with an opening for flowing gas to the filter plate (2), the filter plate (2) being arranged corresponding to the opening, and the diffuser plate (3) being arranged below the filter plate (2), wherein the gas is vertically blown to the surface of a wafer to be processed after passing through the gas intake unit (1), the filter plate (2), and the diffuser plate (3) in sequence;
the gas guide unit (4) comprises at least one gas guide plate (42), and the at least one gas guide plate (42) is arranged at the position of a gas guide port (13) of the gas intake unit (1).

2. The gas control device according to claim 1, wherein the gas intake unit (1) comprises a control area (11) and a gas intake area (12), the gas guide unit (4) is arranged in a transition area between the control area (11) and the gas intake area (12), and the gas guide port (13) is arranged in the transition area;
the gas intake area (12) is provided on the side of the control area (11) and is connected to the control area (11) through the gas guide port (13).

3. The gas control device according to claim 1, wherein the gas guide unit (4) further comprises an adjustment member (41) and a bottom plate (43);
the adjustment member (41) is provided on the bottom plate (43), the adjustment member (41) is connected to the at least one gas guide plate (42) through the bottom plate (43), and the adjustment member (41) is used for driving the gas guide plate (42) to swing on the bottom plate (43) and fixing the at least one gas guide plate (42).

4. The gas control device according to claim 3, wherein the gas guide unit (4) comprises a linkage mechanism (44) and a plurality of gas guide plates (42) arranged on the linkage mechanism (44), the bottom of at least one gas guide plate (42) is provided with the adjustment member (41), and the adjustment member (41) is used for driving the plurality of gas guide plates (42) to swing synchronously through the linkage mechanism

5. The gas control device according to claim 4, wherein the linkage mechanism comprises a plurality of first connecting rods (441) and a plurality of second connecting rods (442), the first connecting rods (441) and the second connecting rods are respectively arranged on both sides of the bottom plate (43), and the first connecting rods (441) and the second connecting rods (442) are parallel;
both ends of each of the gas guide plates (42) are respectively disposed on the first connecting rod (441) and the second connecting rod (442), two of the gas guide plates (42) are disposed on each of the first connecting rods (441) and each of the second connecting rods and the plurality of gas guide plates are arranged parallel and spaced-apart.

6. The gas control device according to claim 5, wherein the linkage mechanism (44) further comprises a first connection position (443) and a second connection position (444), one end of the gas guide plate (42) at the first position is rotationally connected to the first connection position (443), and one end of the gas guide plate at the last position is rotationally connected to the second connection position (444).

7. The gas control device according to claim 5, wherein the plurality of gas guide plates (42) are hinged on the bottom plate (43), the plurality of first connecting rods (441), and the plurality of second connecting rods (442) respectively through a plurality of rotating hinges (445), and the plurality of rotating hinges (445) are used to change the inclination angle of the plurality of gas guide plates (42) relative to the bottom plate (43) during rotation.

8. The gas control device according to claim 2, wherein the diffuser plate (3), the filter plate (2), and the control area (11) are stack sequentially from bottom to top.

9. The gas control device according to claim 3, wherein the gas guide unit (4) comprises a plurality of gas guide plates (42), the adjacent gas guide plates (42) are arranged at the same distance apart, and the swing angles of the plurality of gas guide plates (42) are set to be the same.

10. The gas control device according to claim 1, wherein each of the gas guide plates (42) is provided in a curved surface shape.

11. The gas control device according to claim 2, wherein the diffuser plate (3) comprises a proximal end area and a distal end area, the proximal end area and the distal end area are sequentially arranged along the gas intake direction of the control area (11);
a blocking area (32) is arranged in the diffuser plate (3), the blocking area (32) is arranged on the side of the proximal end area that is away from the distal end area, and the blocking area (32) is provided with a blocking plate for blocking the flow of gas to the filter plate (2).

12. The gas control device according to claim 2, wherein a plurality of gas blocking plates (111) are arranged in the control area (11), and the arrangement direction of the gas blocking plates (111) has an included angle with respect to the gas intake direction of the control area (11).

13. The gas control device according to claim 12, wherein the bottom of the gas blocking plates (111) is provided with a second rotating shaft, the second rotating shaft is disposed in the control area (11), and the gas blocking plates (111) are rotated in the control area (11) by the second rotating shaft.

14. The gas control device according to claim 1, wherein the gas guide unit (4) comprises the plurality of gas guide plates (42) and a plurality of adjustment members (41), the number and position of the adjustment members (42) are arranged corresponding to the gas guide plates (42), each of the gas guide plates (42) is arranged on the corresponding adjustment member (41), and each of the adjustment members (41) is used to drive the corresponding gas guide plate (42) to swing and fix the gas guide plate (42).

15. A gas control device, comprising a gas intake unit (1), a filter plate (2), and a diffuser plate (3);
the gas intake unit (1) being formed with an opening for flowing gas to the filter plate (2), the filter plate (2) being arranged corresponding to the opening, the diffuser plate (3) being arranged below the filter plate (2), and the gas being vertically blown to the surface of a wafer to be processed after passing through the gas intake unit (1), the filter plate (2), and the diffuser plate (3) in sequence;
the diffuser plate (3) comprising a plurality of through-holes (31), the depth of the through-holes (31) corresponding to a first area being smaller than the depth of the through-holes (31) corresponding to a second area, wherein the gas flow velocity of the first area is lower than the gas flow velocity of the second area.

16. The gas control device according to claim 15, wherein the gas control device further comprises a gas guide unit (4), the gas intake unit (1) comprises a control area (11) and a gas intake area (12), the gas guide unit (4) is arranged in a transition area between the control area (11) and the gas intake area (12), and a gas guide port (13) is arranged in the transition area;
the gas intake area (12) is provided on the side of the control area (11) and is connected to the control region (11) through the gas guide port (13).

17. The gas control device according to claim 16, wherein the height of the through-holes (31) increases linearly from the proximal end to the distal end of a gas inlet (121) close to the gas intake area (12) along the diagonal direction of the diffuser plate (3).

18. The gas control device according to claim 17, wherein the height of the through-holes (31) increases along the gas intake direction of the control area (11).
